(19) United States
(12) Patent Application Publication
(10) Pub. No.: US 2003/0020643 A1
(43) Pub. Date: Jan. 30, 2003

(54) Method and chip design for increasing yield of analogue/digital converter chips

(76) Inventors: Wei-Hsin Chen, Er-Lin Chen (TW); Yuan-Chuan Yu, Hsinchu (TW); Yuh-Chin Huang, Pu-Tz (TW)

Correspondence Address: J.C. Patents, Inc., Suite 250, 4 Venture, Irvine, CA, 92618, US

(21) Appl. No.: 09/976,761

(22) Filed: Oct. 12, 2001

(30) Foreign Application Priority Data
Jul. 24, 2001 (TW) 90118006

(51) Int. Cl. H03M 1/06

(52) U.S. Cl. 341/120

(57) ABSTRACT

A method and a chip design for increasing the product yield of analogue/digital converter. First, a specification curve and a characteristic curve of the analogue/digital converter chip are determined. According to the specification curve and the characteristic curve, an adjustment model is built. The characteristic curve of the analogue/digital converter chip is adjusted to correspond to the specification curve according to the adjustment model. The analogue/digital converter chip has an adjustment device therein. The analogue/digital converter converts input analogue signal into a digital output signal. The adjustment device converts the digital output signal into an output signal that meets the specification curve according to an in-built adjusting model.

### CROSS-REFERENCE TO RELATED APPLICATION

This application claims the priority benefit of Taiwan application serial no. 90118006, filed Jul. 24, 2001.

### BACKGROUND OF THE INVENTION

1. Field of Invention

The present invention relates to an analogue/digital converter chip. More particularly, the present invention relates to a method and chip design for increasing the yield of analogue/digital converter chips.

2. Description of Related Art

In the past, five batches of products are normally set aside for testing after a type of chip having analogue/digital converter function (ADC chip) is designed. The items to be tested depend on the desired analogue operating points. For example, an input voltage of Vi1-Vix to the ADC chip is able to measure an output voltage of Vo1-Vox. By averaging the output voltages of various samples, average voltages Vavg1-Vavgx are obtained. Using the average voltages Vavg1-Vavgx as application standards, an almost linear curve showing the relationship between the input voltage and the output voltage can be plotted out as shown in FIG. 1. With such characteristic curve as a standard, quality of other ADC chips can be determined.

However, in mass production, characteristics of the ADC chip may vary from batch to batch. FIG. 2 is a plot of various batches of ADC chips on an input voltage versus output voltage graph As shown in FIG. 2, line ‘b’ is the originally determined standard. If line ‘b’ is chosen as the standard of measurement, an ADC chip having a line ‘a’ or a line ‘c’ characteristic will fail the measurement. Consequently, a larger portion of ADC chips may fail leading to a low product yield.

### SUMMARY OF THE INVENTION

Accordingly, one object of the present invention is to provide a method and a chip design for increasing the product yield of analogue/digital converter (ADC) chips. The method or chip design is capable of converting functional ADC chips that do not meet a specified standard, such as chips having a line ‘a’ or a line ‘b’ characteristic, into ADC chips that meet the specified standard so that product yield of the ADC chips is increased.

To achieve these and other advantages and in accordance with the purpose of the invention, as embodied and broadly described herein, the invention provides a method of increasing the product yield of analogue/digital converter chips. First, a specification curve and a characteristic curve of the analogue/digital converter chip are provided. According to the specification curve and the characteristic curve, an adjustment model is built. The value of the characteristic curve of the analogue/digital converter chip is converted into a corresponding value of the specification curve according to the adjustment model. Therefore, the characteristic curve of the analogue/digital converter chip can be adjusted on demand.

This invention also provides an analogue/digital converter chip having an adjustment device therein. The analogue/digital converter receives an analogue input signal and converts the signal into a digital signal according to the analogue/digital converter characteristic curve of the analogue/digital device. The adjustment device receives the digital output signal and converts the digital signal into an output signal that meet the specification curve according to an in-built adjusting model.

The method and chip design provided by this invention use the same analogue/digital converter chip to measure and increase yield. The analogue/digital chip is not limited by standard specifications. The adjusting model provides a means of adjusting the characteristic curve of the analogue/digital chip to reproduce the specification curve, thereby increasing the production yield.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a graph showing the characteristic curve of a conventional ADC chip;

FIG. 2 is a graph showing the characteristic curves of three different types of conventional ADC chips;

FIG. 3 is a flow chart showing the steps for increasing the yield of analogue/digital converter chips according to one preferred embodiment of this invention;

FIG. 4 is a flow chart showing the steps for obtaining the characteristic curve of an ADC chip according to one preferred embodiment of this invention;

FIG. 5 is a graph showing the characteristic curve of an ADC chip according to one preferred embodiment of this invention; and

FIG. 6 is a block diagram showing an ADC chip according to one preferred embodiment of this invention.

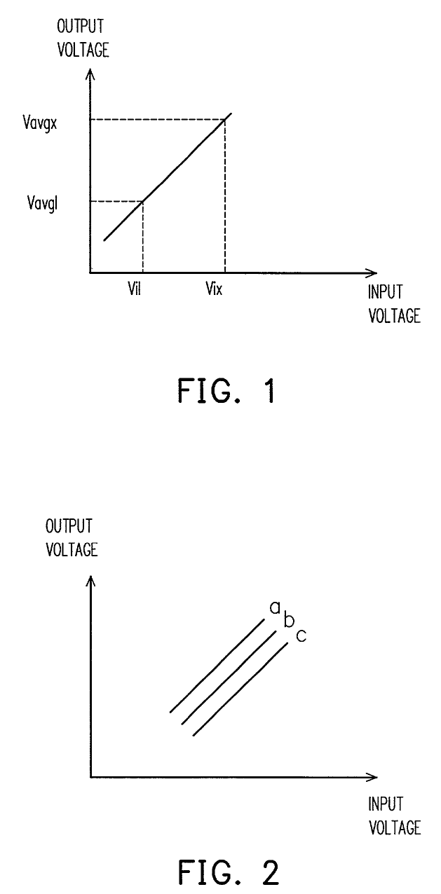

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

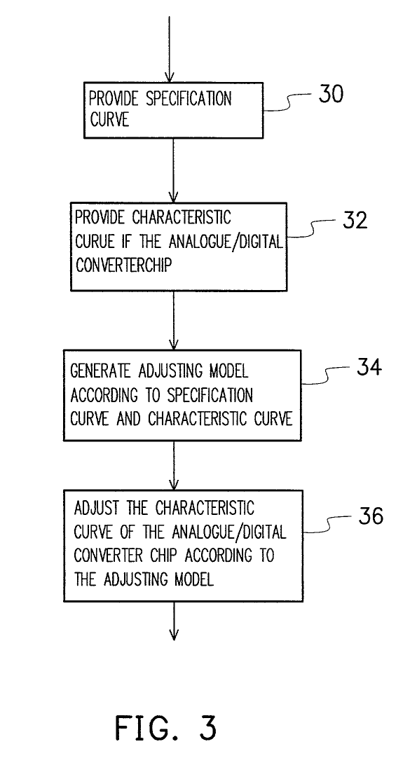

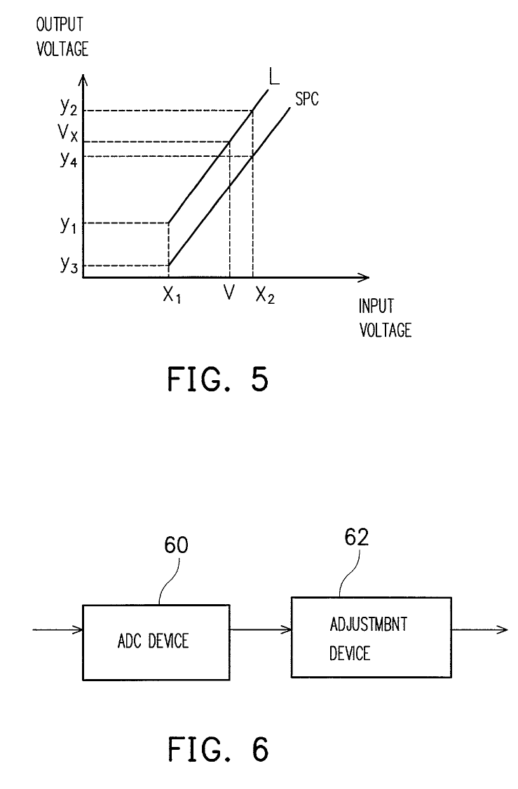

FIG. 3 is a flow chart showing the steps for increasing the yield of analogue/digital converter (ADC) chips according to one preferred embodiment of this invention. In step 30, a specification curve SPC as shown in FIG. 5 is provided. In step 32, a characteristic curve L as shown in FIG. 5 for the ADC is provided. Step 34 is executed when both the specification curve SPC and the characteristic curve L are obtained. In step 34, an adjusting model is established according to the specification curve SPC and the characteristic curve L of the ADC chip. Finally, in step 36, the value of the characteristic curve of the ADC chip is converted into the value corresponding to the specification curve according to the adjusting model. Ultimately, the characteristic curve of the ADC chip is adjusted. For example, an input voltage X1=3V applied to the ADC chip produces a corresponding output voltage Y1=6V. With a specification curve SPC X1=3V, a corresponding output voltage Y3=1V is produced. Therefore, the adjusting model should be arranged in such a way that whatever voltage the ADC chip outputs, the voltage must be downward adjusted by 5V. With such downward adjustment of voltage, the ADC chip will meet the specification curve.

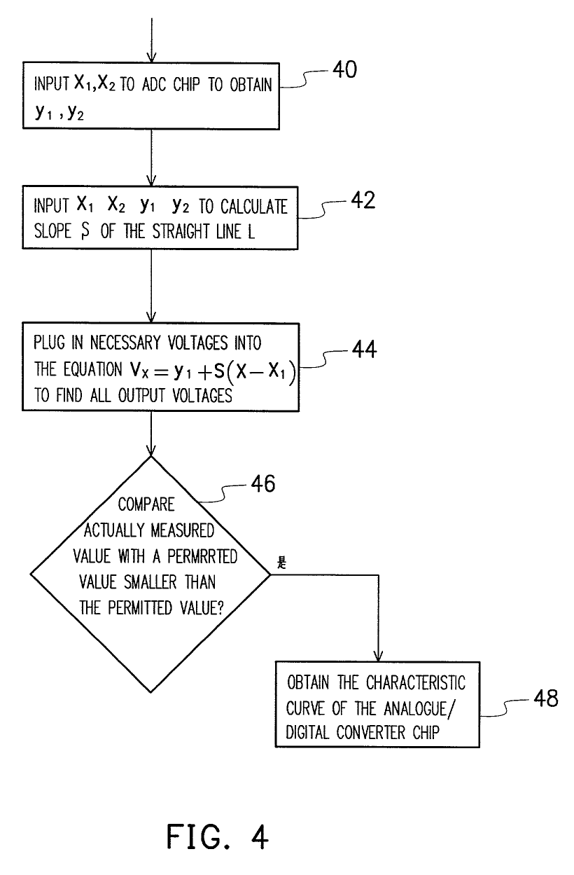

FIG. 4 is a flow chart showing the steps for obtaining the characteristic curve of an ADC chip according to one preferred embodiment of this invention. FIG. 5 is a graph showing the characteristic curve of an ADC chip according to one preferred embodiment of this invention. To obtain the characteristic cure of an ADC chip, the steps shown in FIG. 4 are carried out. In step 40, two input voltages (x1 and x2 in FIG. 5) are input to the analogue/digital converter chip to be measured. The analogue/digital converter outputs two corresponding voltages (y1 and y2 in FIG. 5).

After obtaining a relationship between the input voltages x1 and x2 and corresponding output voltages y1 and y2, step 42 is carried out. In step 42, the input voltage x1, the input voltage x2, the output voltage y1 and the output voltage y2 are plugged into a straight-line equation L: S=(y2−y1)/(x2−x1) to find the value of the slope S.

After securing the straight-line equation of the ADC chip to be measured, step 44 is carried out. In step 44, the measured input voltage is fed to the ADC chip so that the ADC chip produces the measured output voltage. The measured voltage is plugged into the straight-line equation L. For example, the measured input voltage is assumed to be x1 while the known value of the slope S, the input voltage x2 and the output voltage y2 are all plugged into the straight-line equation to find y1, the predicted output voltage. Anyone familiar with the technique may uses other method of utilizing the straight-line equation L to obtain the predicted output voltage. Finally, by subtracting the predicted output voltage from the measured output voltage or vice versa and taking the absolute value, an error value is produced.

Finally, after finding the error value, step 46 is executed. In step 46, the error value is compared with a permitted value. If the error value is smaller than the permitted value, step 48 is executed to obtain the characteristic curve of the ADC chip similar to L shown in FIG. 5. The permitted value indicates a maximum tolerance for error.

FIG. 6 is a block diagram showing an ADC chip according to one preferred embodiment of this invention. As shown in FIG. 6, the ADC chip includes an ADC device 60 and an adjusting device 62. The ADC device 60 is coupled to the adjusting device 62. As soon as the analogue/digital converter 60 receives an analogue input signal, the analogue input signal is converted into a digital signal according to the analogue/digital characteristic curve of the analogue/digital converter 60. The digital signal is transmitted to the adjusting device 62. The adjusting device 62 converts the digital signal into a digital output signal value that corresponds to an input analogue signal at the specification curve according to a built-in adjustment model. The digital output signal value is transmitted as an adjusted output voltage. Anyone familiar with the technique may know that the adjusting device 62 can be implemented by hardware circuits or firmware.

In summary, this invention provides an adjusting device for converting ADC chips having characteristic curve that do not meet the specification curve, such as having a line ‘a’ ADC chips or a line ‘c’ ADC chips, into ADC chips having the specification curve. Thus, overall product yield of the ADC chips is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of increasing the yield of analogue/digital converter chips, comprising:
providing a specification curve;
providing a characteristic curve for the analogue/digital converter chips;
generating an adjustment model according to the specification curve and the characteristic curve; and
adjusting the characteristic curve of the analogue/digital converter chip according to the adjustment model.

2. The method of claim 1, wherein providing the characteristic curve of the analogue/digital converter chips includes:
providing a first input voltage and a second input voltage;
generating a first output voltage and a second output voltage according to the first input voltage and the second input voltage fed to the analogue/digital converter chip;
plugging respective values of the first input voltage, the second input voltage, the first output voltage and the second output voltage into a straight-line equation: S=(y2−y1)/(x2−x1) to obtain a slope value S, where y2 is the second output voltage, y1 is the first output value, x2 is the second input voltage and x1 is the first input voltage;
inputting a measuring input voltage into the analogue/digital converter chip to produce a measuring output voltage;
finding a predicted measuring output voltage by plugging the measuring input voltage into the straight-line equation;
finding an error value by subtracting the predicted measuring output voltage from the measuring output voltage or by subtracting the measuring output voltage from the predicted measuring output voltage; and
obtaining the characteristic curve of the analogue/digital converter chip when the error value is smaller than a permitted value.

3. The method of claim 1, wherein the adjustment model converts a value of the characteristic curve of the analogue/digital converter chip into a value corresponding to the specification curve.

4. An analogue/digital converter chip having an analogue/digital converter characteristic curve that differs from a specification curve, comprising:
an analogue/digital converter for converting an analogue signal into a digital signal according to the characteristic curve of the analogue/digital converter; and
an adjusting device for receiving the digital signal and converting the digital signal into an adjusted output signal that meets the specification curve according to an adjustment model.

5. The chip of claim 4, wherein the adjustment model converts the digital output signal into a digital value corresponding to the specification curve resulting from an analogue input signal and uses the digital output value as the adjusted output signal.

6. The chip of claim 4, wherein the adjustment device is implemented using hardware circuits.

7. The chip of claim 4, wherein the adjustment device is implemented using firmware products.
